(19) United States
(12) Patent Application Publication
(10) Pub. No.: US 2019/0043990 A1
(43) Pub. Date: Feb. 7, 2019

(54) THIN FILM TRANSISTOR

(71) Applicant: Sharp Kabushiki Kaisha, Sakai City, Osaka (JP)

(72) Inventors: Yohsuke KANZAKI, Sakai City (JP); Takao SAITOH, Sakai City (JP); Seiji KANEKO, Sakai City (JP)

(21) Appl. No.: 16/073,345

(22) PCT Filed: Feb. 21, 2017
(86) PCT No.: PCT/JP2017/006373

§ 371 Date: Jul. 27, 2018

(30) Foreign Application Priority Data
Feb. 29, 2016 (JP) 2016-036707

(51) Int. Cl. H01L 29/786; C23C 16/34; C23C 16/40

(52) U.S. Cl. CPC H01L 29/7869; C23C 16/401; C23C 16/345; H01L 29/78618

(57) ABSTRACT

A thin film transistor (TFT) 11 includes a gate electrode 11a, a channel section 11d formed of an oxide semiconductor film 17, a source electrode 11b connected to one end of the channel section 11d, and a drain electrode 11c connected to another end of the channel section 11d, and the oxide semiconductor film 17 is an oxide semiconductor containing at least gallium and indium and an atomic ratio Ga/(Ga+In) is from 1/4.2 to 1/3.3.

### TECHNICAL FIELD

The present invention relates to a thin film transistor.

### BACKGROUND ART

A thin film transistor described in Patent Document 1 has been known as a switching component included in a display panel such as a liquid crystal panel. In such a thin film transistor, an oxide thin film includes indium oxide and gallium solid-solved therein, the oxide thin film having an atomic ratio “Ga(Ga+In)” of 0.001 to 0.12, containing indium and gallium in an amount of 80 atom % or more based on total metal atoms, and having an In₂O₃ bixbyite structure.

### RELATED ART DOCUMENT

### Patent Document

Patent Document 1: Japanese Unexamined Patent Application Publication No. 2012-250910

### Problem to be Solved by the Invention

However, in the thin film transistor described in Patent Document 1, the oxide thin film used in the channel layer has an In₂O₃ bixbyite structure, and includes a large number of defect levels caused by grain boundaries. Therefore, characteristics of the thin transistor are not good.

### DISCLOSURE OF THE PRESENT INVENTION

The present invention was made in view of the above circumstances and an object is to improve characteristics.

### Means for Solving the Problem

A thin film transistor substrate according to the present invention includes a gate electrode, a channel section formed of an oxide semiconductor film, a source electrode connected to one end of the channel section, and a drain electrode connected to another end of the channel section, and the oxide semiconductor film is an oxide semiconductor containing at least gallium and indium and an atomic ratio Ga/(Ga+In) is from 1/4.2 to 1/3.3.

According to such a configuration, if a signal is supplied to the gate electrode, the electron moves from the source electrode to the drain electrode via the channel section that is formed of the oxide semiconductor. If the oxide semiconductor film of the channel section has the atomic ratio Ga/(Ga+In) that is greater than 1/3.3, the subthreshold swing value (subthreshold coefficient) is greater than 0.5 V/dec and the switching properties of the TFT may be deteriorated. This may be caused because the content ratio of indium oxide having a bixbyite structure of a cubic crystal system in the oxide semiconductor film is increased and a defect density caused by grain boundaries is extremely great. If the atomic ratio Ga/(Ga+In) of the oxide semiconductor film is smaller than 1/4.2, the electron mobility may be quite lower than 20 cm²/Vs because the atomic ratio of In to Ga in the oxide semiconductor film may be too low. The atomic ratio Ga/(Ga+In) of the oxide semiconductor film is within a range of 1/4.2 to 1/3.3 and accordingly, the subthreshold swing value is 0.5 V/dec or smaller and the electron mobility is 20 cm²/Vs or more so that the characteristics of the thin film transistor are improved.

Preferable embodiments of present invention may include the following configurations.

(1) In the oxide semiconductor film, the atomic ratio Ga/(Ga+In) may be from 1/4.2 to 1/3.7. According to such a configuration, the electron mobility in the oxide semiconductor film is 30 cm²/Vs or more so that the characteristics of the thin film transistor are further improved.

(2) In the oxide semiconductor film, the atomic ratio Ga/(Ga+In) may be 1/4.2. According to such a configuration, the subthreshold swing value in the oxide semiconductor film is smallest and the electron mobility is highest so that the characteristics of the thin film transistor are further improved.

### Advantageous Effect of the Invention

According to the present invention, characteristics can be improved.

### BRIEF DESCRIPTION OF THE DRAWINGS

FIG. 1 is a schematic cross-sectional view illustrating a cross-sectional configuration of a liquid crystal panel according to a first embodiment of the present invention.

FIG. 2 is an enlarged plan view illustrating a plan-view configuration of an array board of the liquid crystal panel in a display section.

FIG. 3 is an enlarged plan view illustrating a plan-view configuration of a CF board of the liquid crystal panel in the display section.

FIG. 4 is a cross-sectional view taken along line A-A in FIG. 2.

FIG. 5 is a graph representing relation of diffraction intensity and diffraction angles in Comparative Example 1 of Comparative Experiment 1.

FIG. 6 is a graph representing relation of diffraction intensity and diffraction angles in Comparative Example 2 of Comparative Experiment 1.

FIG. 7 is a graph representing relation of diffraction intensity and diffraction angles in Example 1 of Comparative Experiment 1.

FIG. 8 is a graph representing relation of diffraction intensity and diffraction angles in Example 2 of Comparative Experiment 1.

FIG. 9 is a graph representing relation of diffraction intensity and diffraction angles in Example 3 of Comparative Experiment 1.

FIG. 10 is a graph representing relation of diffraction intensity and diffraction angles in Comparative Example 3 of Comparative Experiment 1.

FIG. 11 is a graph representing relation of drain currents and gate voltages in Comparative Example 1 of Comparative Experiment 2.

FIG. 12 is a graph representing relation of drain currents and gate voltages in Comparative Example 2 of Comparative Experiment 2.

FIG. 13 is a graph representing relation of drain currents and gate voltages in Example 1 of Comparative Experiment 2.

FIG. 14 is a graph representing relation of drain currents and gate voltages in Example 2 of Comparative Experiment 2.

FIG. 15 is a graph representing relation of drain currents and gate voltages in Example 3 of Comparative Experiment 2.

FIG. 16 is a graph representing relation of drain currents and gate voltages in Comparative Example 3 of Comparative Experiment 2.

FIG. 17 is a table illustrating Vth, S values, and μ values in Comparative Examples 1-3 and Examples 1-3 of Comparative Experiment 2.

FIG. 18 is a graph representing relation of S values, μ values and an atomic ratio “Ga(Ga+In)” in Comparative Examples 1-3 and Examples 1-3 of Comparative Experiment 2.

### MODES FOR CARRYING OUT THE INVENTION

### First Embodiment

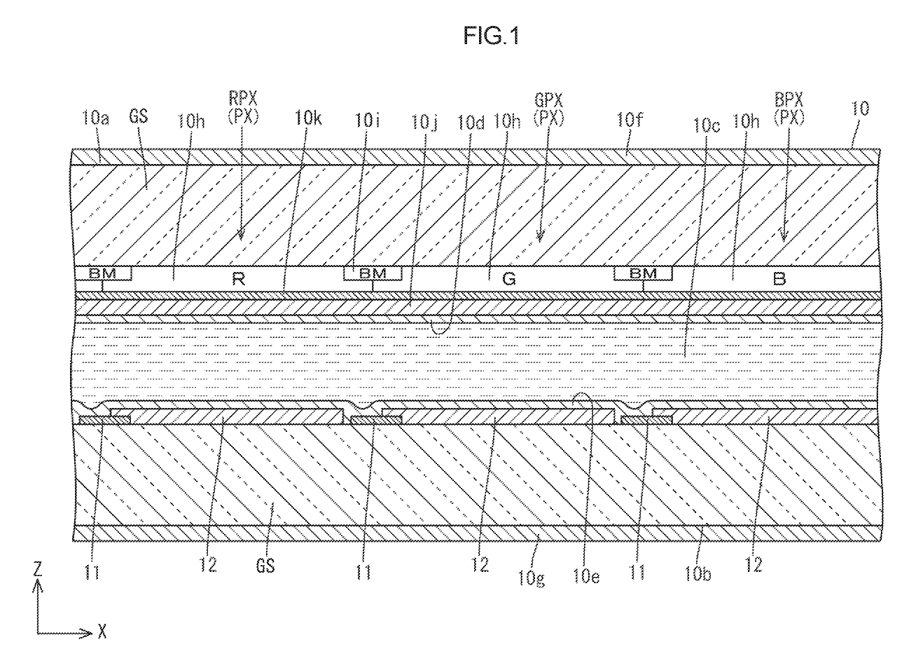

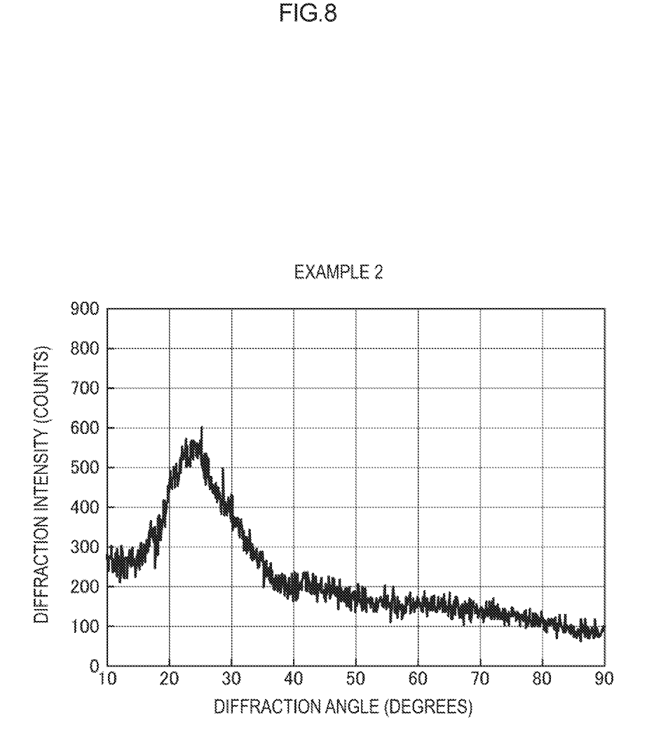

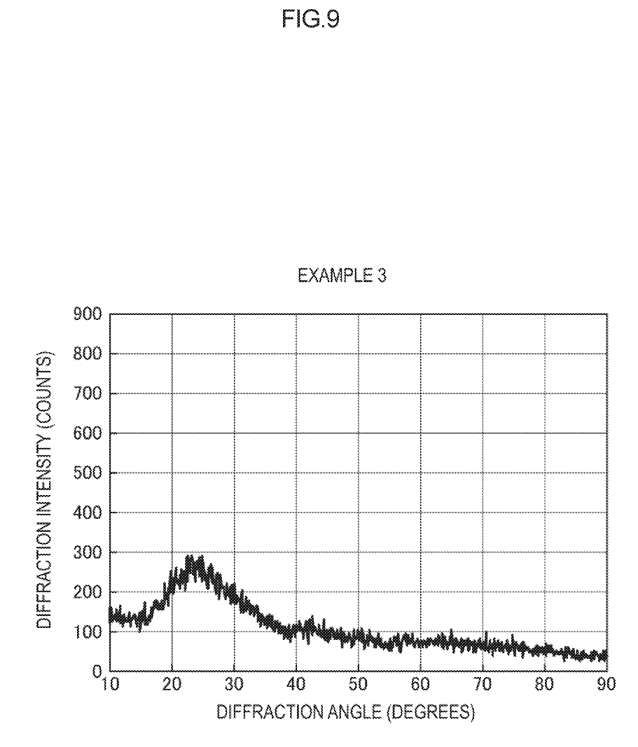

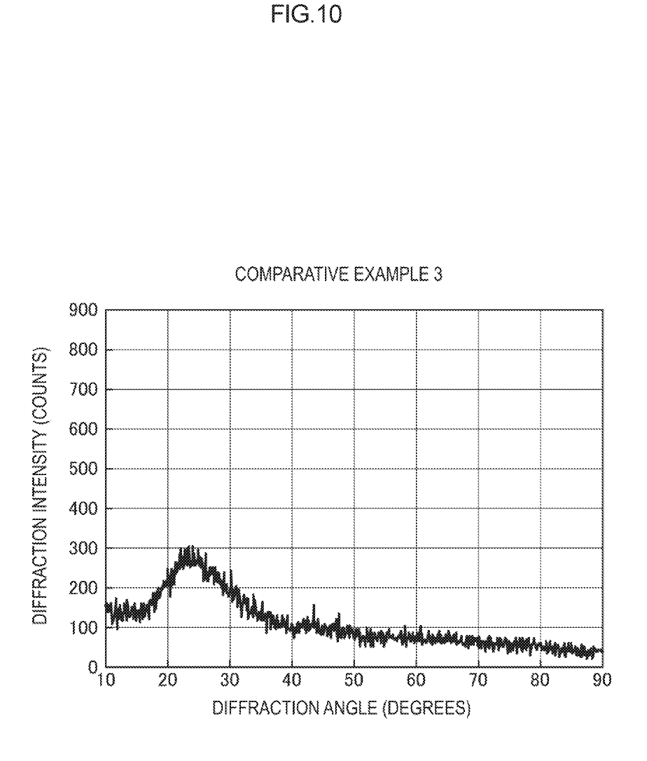

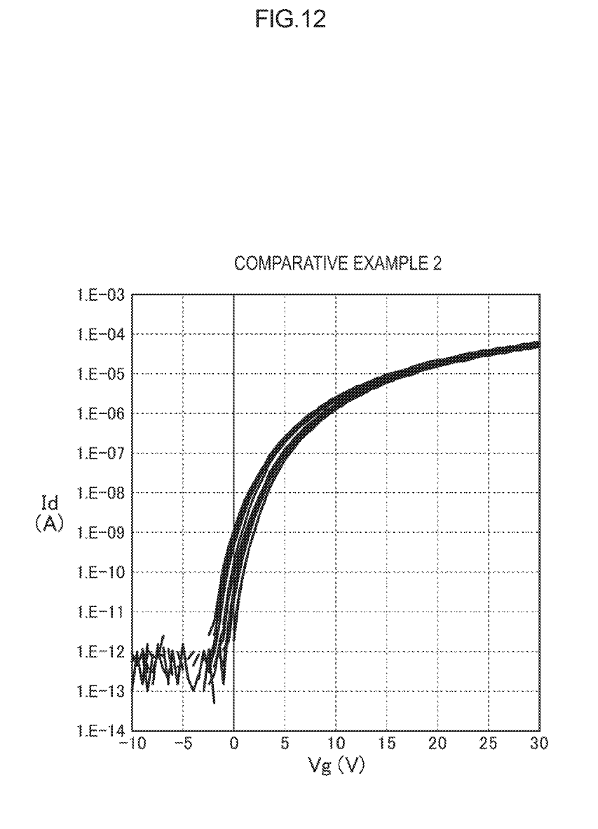

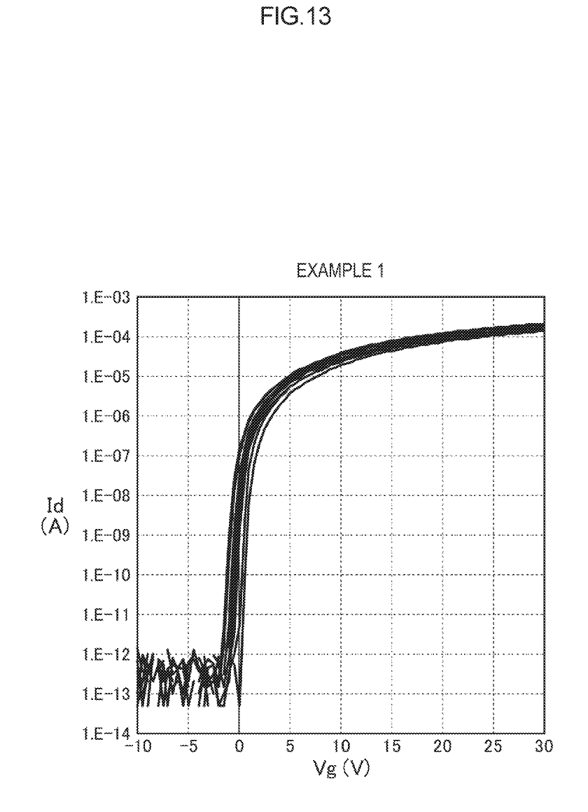

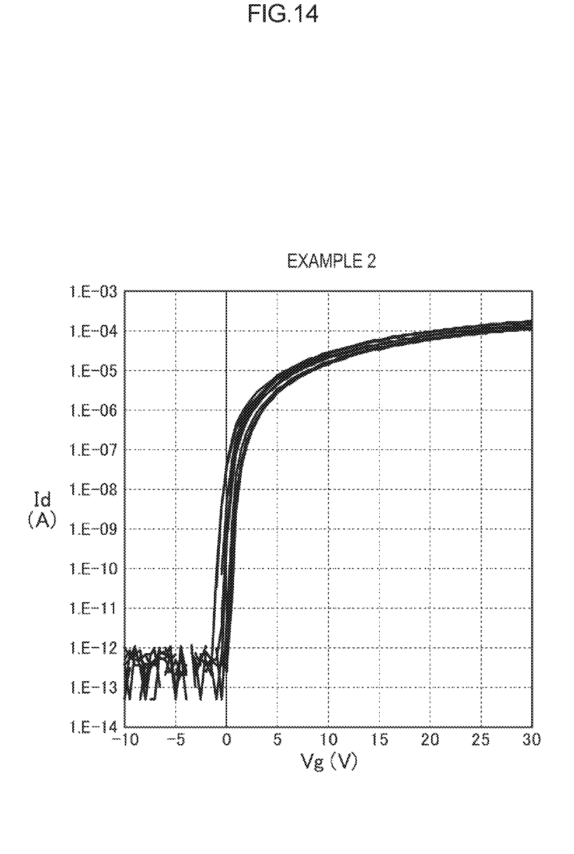

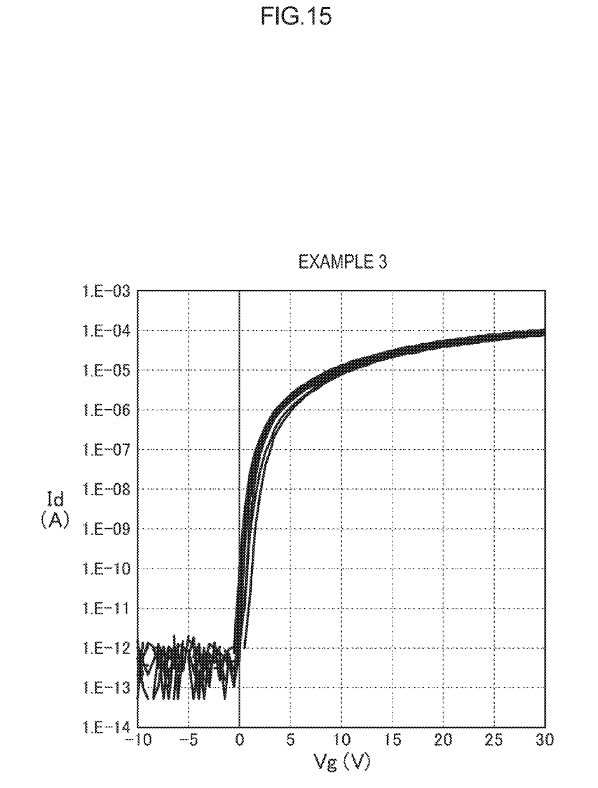

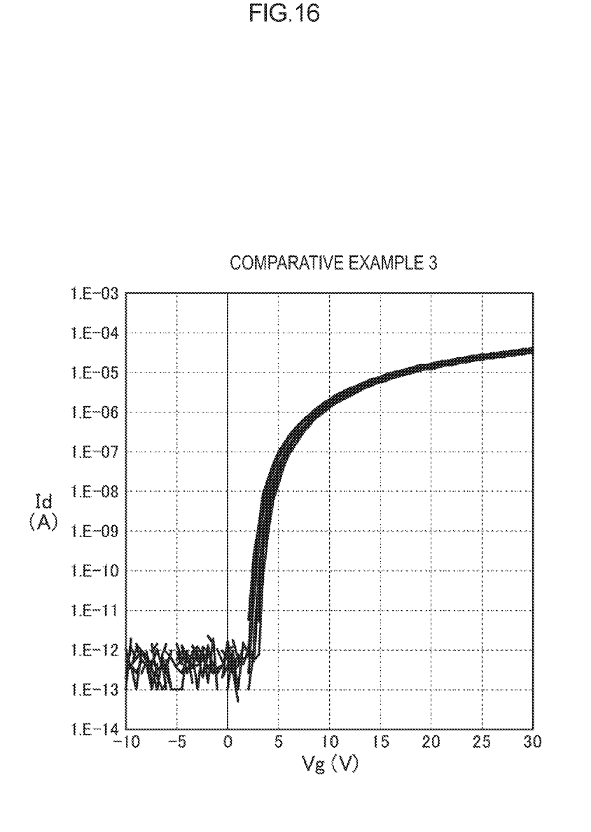

A first embodiment of the present invention will be described with reference to FIGS. 1 to 18. In this embodiment, thin film transistors (TFTs) 11 included in a liquid crystal panel (a display panel) 10 will be described. X-axis, Y-axis and Z-axis may be indicated in some of the drawings. The axes in each drawing correspond to the respective axes in other drawings.

A configuration of the liquid crystal panel 10 will be described. As illustrated in FIG. 1, the liquid crystal panel 10 includes a pair of transparent (having high light transmissivity) substrates 10a and 10b and a liquid crystal layer 10c between the substrates 10a and 10b. The liquid crystal layer 10c includes liquid crystal molecules having optical characteristics that vary according to application of electric field. The substrates 10a and 10b are bonded together with a sealing agent, which is not illustrated, with a cell gap therebetween. A size of the cell gap corresponds to the thickness of the liquid crystal layer 10c. Each of the substrates 10a, 10b includes a substantially transparent glass substrate GS and various films are formed in layers on the glass substrate GS with the known photolithography method. One of the substrates 10a and 10b on the front (a front side) is a CF board (a counter substrate) 10a and one on the rear (a back side) is an array board (a thin film transistor substrate, an active matrix substrate) 10b. Polarizing plates 10f and 10g are attached to outer surfaces of the substrates 10a and 10b, respectively. Alignment films 10d and 10e are formed on inner surfaces of the substrates 10a and 10b, respectively, for alignment of the liquid crystal molecules included in the liquid crystal layer 10c.

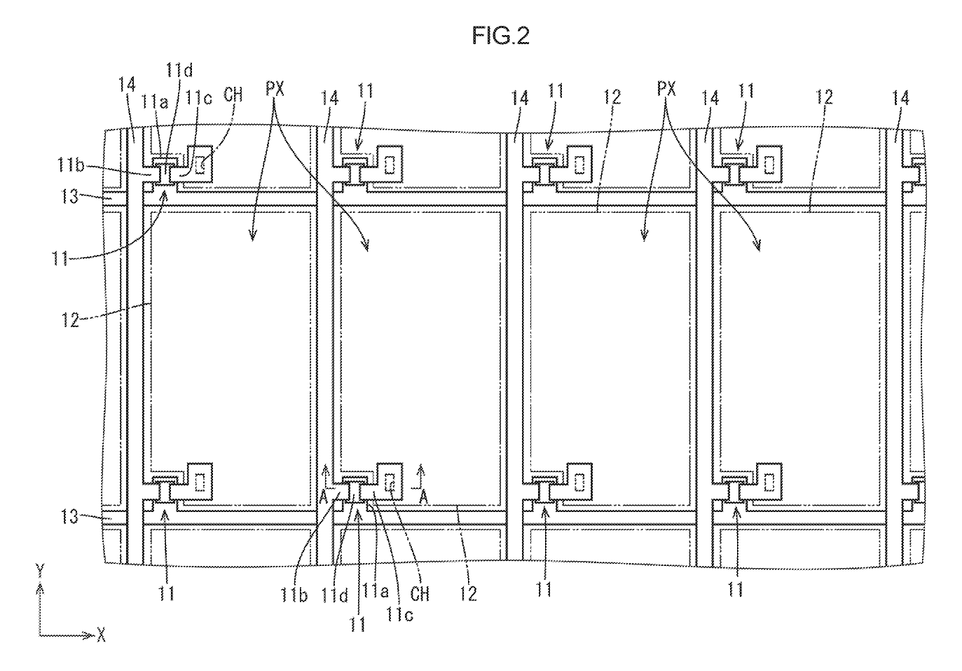

As illustrated in FIGS. 1 and 2, on the inner surface of the array board 10b in the display section that is a middle of a screen and where images are displayed (on a liquid crystal layer 10c side, on a CF board 10a opposite surface side), thin film transistors (TFTs) 11, which are switching components, and pixel electrodes 12 are disposed in a matrix. Furthermore, gate lines 13 and source lines 14 are routed in a matrix around the TFTs 11 and the pixel electrodes 12. Namely, the TFTs 11 and the pixel electrodes 12 are arranged in a matrix at respective corners defined by the gate lines 13 and the source lines 14 that are formed in a matrix. The pixel electrode 12 has a vertically-elongated square (rectangular) shape in a plan view overlapping an area surrounded by the gate lines 13 and the source lines 14. The array board 10b may include an auxiliary capacitance electrode (not illustrated) that extends parallel to the gate lines 13 and crosses the pixel electrode 12.

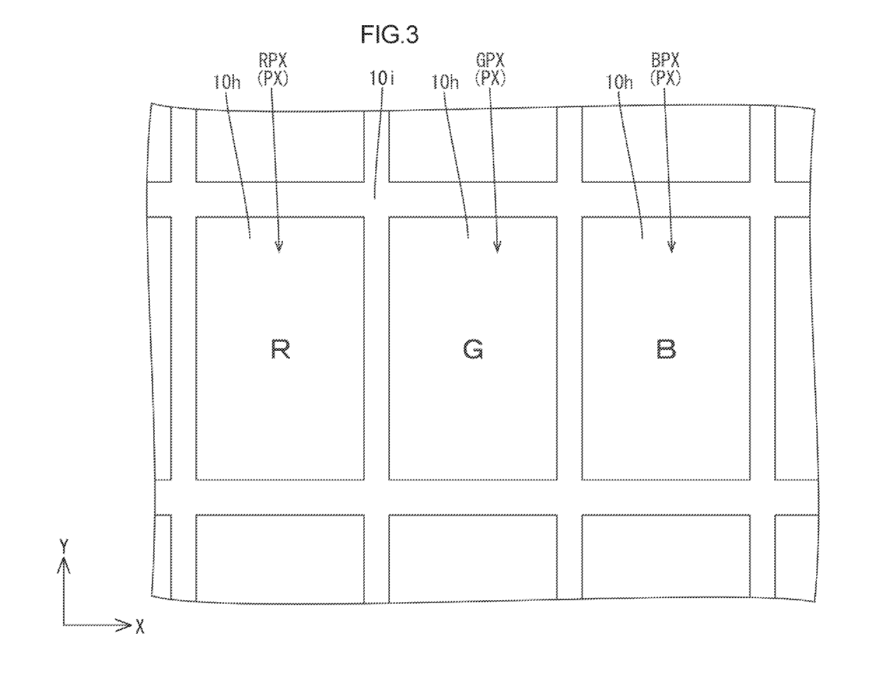

As illustrated in FIGS. 1 and 3, the CF board 10a includes color filters 10h including red (R), green (G), and blue (B) color portions on the inner surface thereof (on the liquid crystal layer 10c side, a surface opposite the array board 10b). The color portions of the color filters 10h are arranged in a matrix in the row direction (the X-axis direction) and the column direction (the Y-axis direction) so as to overlap the respective pixel electrodes 12 on the array board 10b in a plan view. A light blocking section (a black matrix, a light blocking section) 10i is formed in a grid and arranged between the color portions of the color filters 10h for preventing colors from mixing. The light blocking section 10i is arranged over the gate lines 13 and the source lines 14 in a plan view. Each of the color portions of the color filters 10h is thicker than the light blocking section 10i and is disposed to cover the light blocking section 10i. Each display pixel PX of the liquid crystal panel 10 includes three color portions, that is, R, G and B color portions of the color filters 10h and three pixel electrodes 12 opposite the color portions, respectively, and three TFTs 11 connected to the respective pixel electrodes 12. The display pixels PX include a red pixel RPX including the R color portion, a green pixel GPX including the G color portion, and a blue pixel BPX including the B color portion. The pixels RPX, GPX, BPX are arranged on the plate surface of the liquid crystal panel 10 in a repeated sequence along the row direction (the X-axis direction) and form groups of pixels. The groups of pixels are arranged along the column direction (the Y-axis direction).

As illustrated in FIG. 1, an overcoat film 10k is disposed over inner surfaces of the color filters 10h and the light blocking section 10i. The overcoat film 10k is disposed in a solid pattern over a substantially entire area of the inner surface of the CF board 10a and has a film thickness same as or larger than that of the color filter 10h. A counter electrode 10j is disposed over an inner surface of the overcoat film 10k. The counter electrode 10j is disposed in a solid pattern over a substantially entire area of the inner surface of the CF board 10a. The counter electrode 10j is made of transparent electrode material such as indium tin oxide (ITO). The counter electrode 10j is always maintained at a constant reference potential. If a potential is supplied to each pixel electrode 12 connected to each TFT 11 according to driving of each TFT 11, potential difference is generated between the counter electrode 10j and each pixel electrode 12. Alignment state of the liquid crystal molecules contained in the liquid crystal layer 10c is altered according to the potential difference generated between the counter electrode 10j and each pixel electrode 12. Accordingly, polarization of the transmission light is altered. Thus, the transmission light amount of the liquid crystal panel 10 is controlled for every display pixel PX independently and a predetermined color image can appear on the display panel.

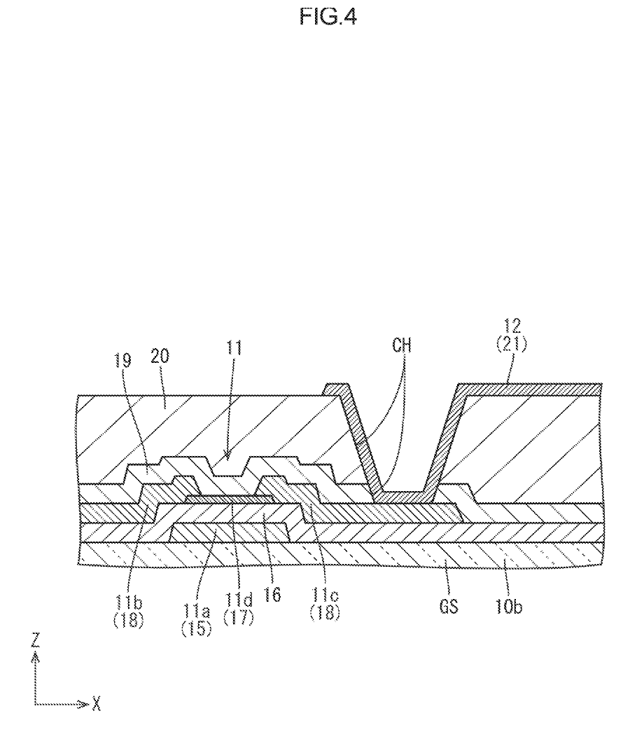

The various films formed in layers on the inner surface of the array board 10b will be described. As illustrated in FIG. 4, on the array board 10b, the following films are formed in the following order from the lowest layer (the grass substrate GS): a first metal film (a gate metal film) 15, a gate insulation film 16, an oxide semiconductor film 17, a second metal film (a source metal film) 18, an interlayer insulation film 19, a flattening film 20, and a transparent electrode film 21. The alignment film 10e that is disposed in an upper layer with respect to the transparent electrode film 21 is not illustrated in FIG. 4.

The first metal film 15 is a multilayer film including two layers of metal material such as a tungsten (W) layer and a tantalum nitride (TaN) layer. The tungsten layer preferably has a film thickness of approximately 300 nm and the tantalum nitride layer has a film thickness of approximately 20 nm. The first metal film 15 is preferably formed with the sputtering method. The first metal film 15 mainly forms the gate lines 13. As illustrated in FIG. 4, the gate insulation film 16 is included in an upper layer of the first metal film 15. The gate insulation film 16 is a multilayer film including layers of inorganic material such as a silicon oxide (SiO₂) layer and a silicon nitride (SiNₓ) layer. The silicon oxide layer preferably has a film thickness of approximately 50 nm and the silicon nitride layer has a film thickness of approximately 300 nm. The gate insulation film 16 is disposed between the first metal film 15 (such as the gate lines 13) and the second metal film 18 (such as the source lines 14), which will be described later, and the metal films are insulated from each other by the gate insulation film 16. The gate insulation film 16 is preferably formed with the chemical vapor deposition (CVD) method. The oxide semiconductor film 17 is disposed on the gate insulation film 16 and is a thin film made of an oxide semiconductor. The oxide semiconductor film 17 preferably has a film thickness of approximately 50 nm. The semiconductor film 17 is preferably formed with the sputtering method. The oxide semiconductor film 17 is an oxide semiconductor (In—Ga—O semiconductor) containing indium (In), and gallium (Ga). The TFT 11 including such an oxide semiconductor film 17 has high electron mobility (higher than that of an a-SiTFT, for example, 20 times higher or more) and low leakage current (less than 1/100 compared to that of an a-SiTFT).

As illustrated in FIG. 4, the second metal film 18 is included in an upper layer of the oxide semiconductor film 17. The second metal film 18 is a multilayer film including three metal layers such as a titanium (Ti) layer, an aluminum (Al) layer, and a titanium layer. Preferably, the bottom titanium layer has a film thickness of approximately 100 nm, the aluminum layer has a film thickness of approximately 300 nm, and the upper titanium layer has a thickness of approximately 30 nm. The second metal film 18 is preferably formed with the sputtering method. The second metal film 18 mainly forms the source lines 14. The interlayer insulation film 19 is at least above the second metal film 18. The interlayer insulation film 19 is made of inorganic material such as silicon oxide (SiO₂) and preferably has a film thickness of approximately 300 nm. The interlayer insulation film 19 is preferably formed with the CVD method. The flattening film 20 is disposed on the interlayer insulation film 19. The flattening film 20 is made of synthetic resin such as acrylic resin (PMMA). The flattening film 20 has a film thickness of about 2 μm and is relatively greater than that of the interlayer insulation film 19. Therefore, the surface of the array board 10b is flattened. The flattening film 20 is preferably formed with a slit coat method or a spin coating method. The interlayer insulation film 19 and the flattening film 20 are present between the transparent electrode film 21 and each of the second metal film 18 and the oxide semiconductor film 17 and insulation is established therebetween. The transparent electrode film 21 is included in an upper layer of the flattening film 20. The transparent electrode film 21 is made of transparent electrode material such as indium zinc oxide (IZO) and has a film thickness of substantially 100 nm. The transparent electrode film 21 is preferably formed with the sputtering method. The transparent electrode film 21 mainly forms the pixel electrode 12.

A configuration of each TFT 11 will be described in detail. As illustrated in FIGS. 2 and 4, each TFT 11 at least includes a gate electrode 11a, a channel section 11d, a source electrode 11b that is connected to one end of the channel section 11d, and a drain electrode 11c that is connected to another end of the channel section 11d. The gate electrode 11a is formed of the first metal film 15 that forms the gate lines 13 and is a branched section projecting and branched from the gate line 13 in the Y-axis direction (the extending direction of the source line 14). The channel section 11d is formed of the oxide semiconductor film 17 and arranged so as to overlap the gate electrode 11a while having the gate insulation film 16 therebetween. The source electrode 11b is formed of the second metal film 18 that forms the source line 14 and is a branched section projecting and branched from the source line 14 in the X-axis direction (the extending direction of the gate line 13) and a part of the source electrode 11b overlaps the gate electrode 11a. The drain electrode 11c is formed of the second metal film 18 that forms the source line 14 and the source electrode 11b and is opposite the source electrode 11b while having a distance for the channel section 11d therebetween. An end of the drain electrode 11c opposite from the channel section 11d side is connected to the pixel electrode 12 through a contact hole CH formed in the interlayer insulation film 19 and the flattening film 20. In this embodiment, the TFT 11 does not include an etch stopping layer on the channel section 11d and is configured such that a lower surface of the end of the source electrode 11b on the channel section 11d side is contacted with an upper surface of the oxide semiconductor film 17.

As described before, the oxide semiconductor film 17 forming the channel section 11d according to this embodiment is formed of an oxide semiconductor containing gallium and indium. An atomic ratio of gallium and indium “Ga(Ga+In)” is in a range of 1/4.2 to 1/3.3 (an atomic ratio of In to Ga is in a range of 2.3 to 3.2 (In:Ga=2.3-3.2:1.0). According to such a configuration, a subthreshold swing value (S value) is effectively small and electron mobility (μ value) in the channel section 11d is effectively large. Therefore, transistor characteristics (switching characteristics) of the TFT 11 are improved. The subthreshold swing value (S value) is gate voltage that is required to be applied in order to create a one decade increase in the current amount flowing from the source electrode 11b to the drain electrode 11c through the channel section 11d in the TFT 11. Especially, if the atomic ratio of gallium and indium “Ga(Ga+In)” is in a range of 1/4.2 to 1/3.7 (the atomic ratio of In to Ga is in a range of 2.7 to 3.2 (In:Ga=2.7-3.2:1.0), the electron mobility in the channel section 11d is further increased and the transistor characteristics of the TFT 11 are further improved. Furthermore, if the atomic ratio of gallium and indium “Ga(Ga+In)” is 1/4.2 (the atomic ratio of In to Ga is 3.2 (In:Ga=3.2:1.0), the subthreshold swing value is smallest and the electron mobility in the channel section 11d is highest and the transistor characteristics of the TFT 11 are best. Thus, the TFT 11 having improved transistor characteristics can be downsized and an aperture ratio of the display pixel PX can be increased and display resolution of the liquid crystal panel 10 is preferably increased.

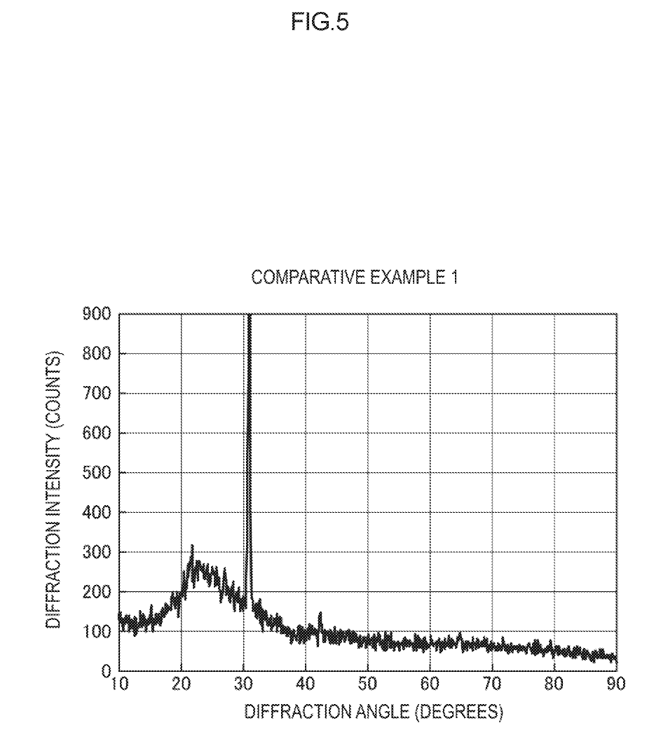

To demonstrate the above-described operations and effects, following Comparative Experiments 1, 2 were performed. First, Comparative Experiment 1 will be described. In Comparative Experiment 1, for the oxide semiconductor films 17 having different atomic ratios “Ga/(Ga+In)”, X-ray diffraction was performed with an X-ray diffraction (XRD) device and diffraction intensity was measured while changing a diffraction angle. In Comparative Experiment 1, for the oxide semiconductor films 17 having different atomic ratios “Ga/(Ga+In)”, an oxide semiconductor film having an atomic ratio “Ga/(Ga+In)” of 1/6.7 (about 0.15)” was used in Comparative Example 1, an oxide semiconductor film having an atomic ratio “Ga/(Ga+In)” of 1/5 (about 0.2)” was used in Comparative Example 2, an oxide semiconductor film having an atomic ratio “Ga/(Ga+In)” of 1/4.2 (about 0.24)” was used in Example 1, and an oxide semiconductor film having an atomic ratio “Ga/(Ga+In)” of 1/3.7 (about 0.27)” was used in Example 2, an oxide semiconductor film having an atomic ratio “Ga/(Ga+In)” of 1/3.3 (about 0.30)” was used in Example 3, and an oxide semiconductor film having an atomic ratio “Ga/(Ga+In)” of 1/2.2 (about 0.45)” was used in Comparative Example 3. In Comparative Experiment 1, after the oxide semiconductor films of Comparative Examples 1-3 and Examples 1-3 were subjected to the annealing treatment under air atmosphere of 450° C., measurement was performed with using an X-ray diffraction device. Experimental results of Comparative Experiment 1 are illustrated in FIGS. 5 to 10. In graphs in FIGS. 5 to 10, a vertical axis represents diffraction intensity (a unit is a count) and a horizontal axis represents diffraction angles (a unit is a degree). The atomic ratio of In to Ga is 5.7 in Comparative Example 1, 4.0 in Comparative Example 2, 3.2 in Example 1, 2.7 in Example 2, 2.3 in Example 3, and 1.2 in Comparative Example 3.

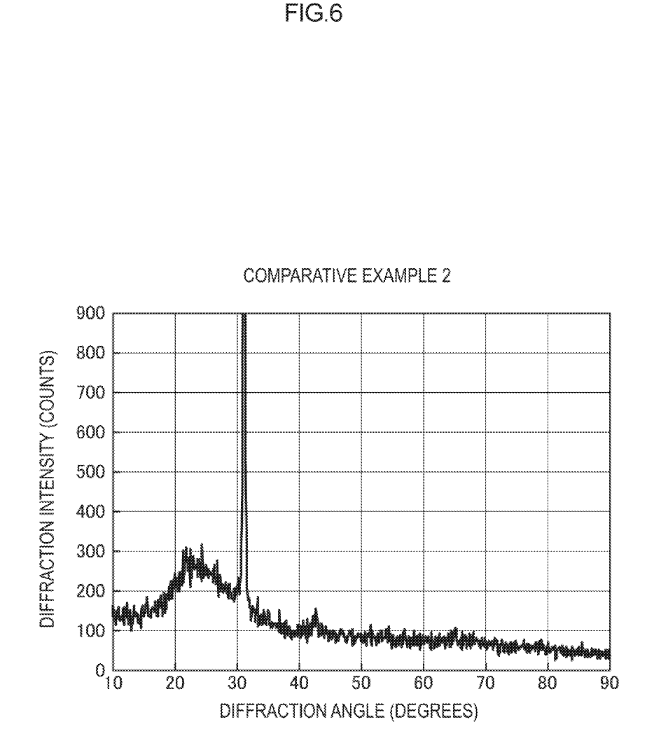

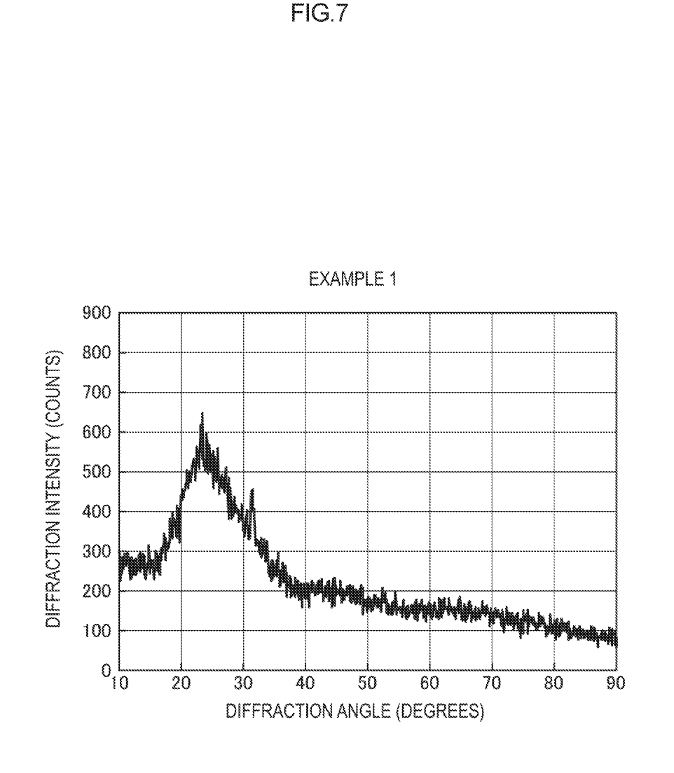

Experimental results of Comparative Experiment 1 will be described. According to the graphs in FIGS. 5 to 10, gentle peak intensities are near the diffraction angle of 25 degrees and such peak intensities are resulted from the glass substrate. According to the graphs in FIGS. 5 and 6, steep peak intensity is near the diffraction angle of 30 degrees in Comparative Examples 1 and 2. Such peak intensity near the diffraction angle of 30 degrees is caused as a characteristic when crystalline of indium oxide (In₂O₃) contained in the oxide semiconductor film is present, and the peak intensity near the diffraction angle of 30 degrees strongly indicates that a bixbyite structure of a cubic crystal system of indium oxide is present. According to the graphs in FIGS. 7 to 10, in Examples 1 to 3 and Comparative Example 3, the steep peak intensity near the diffraction angle of 30 degrees is less likely to be present and it is assumed that a bixbyite structure of a cubic crystal system of indium oxide is less likely to be present. According to the graph in FIG. 7, in Example 1, very gentle peak intensity is near the diffraction angle of 30 degrees and it is assumed that a bixbyite structure of a cubic crystal system of indium oxide is slightly present.

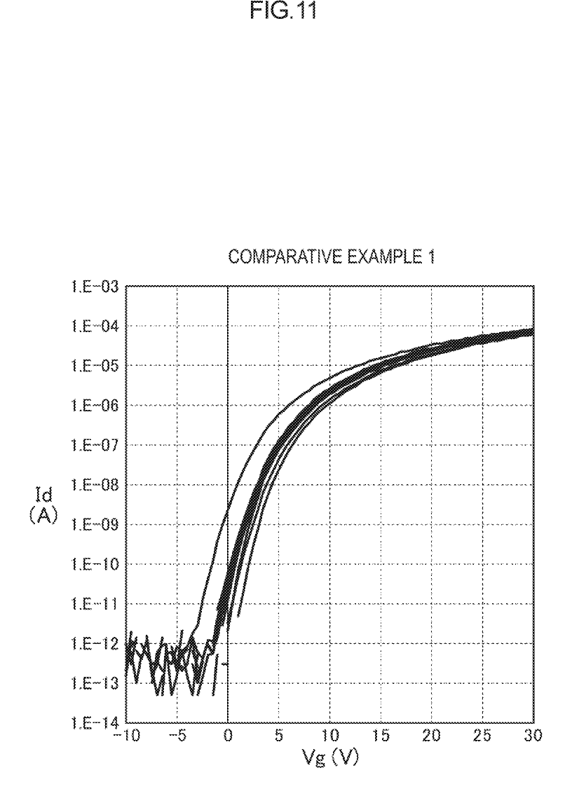

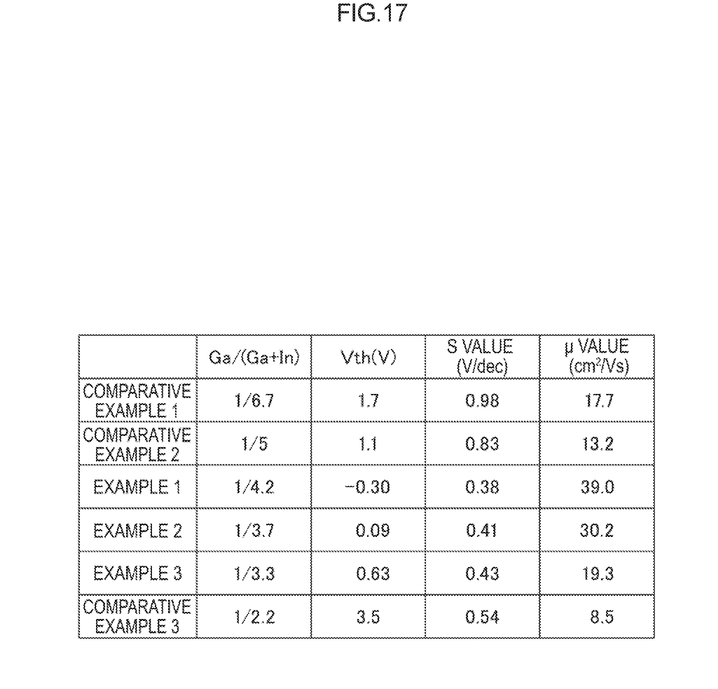

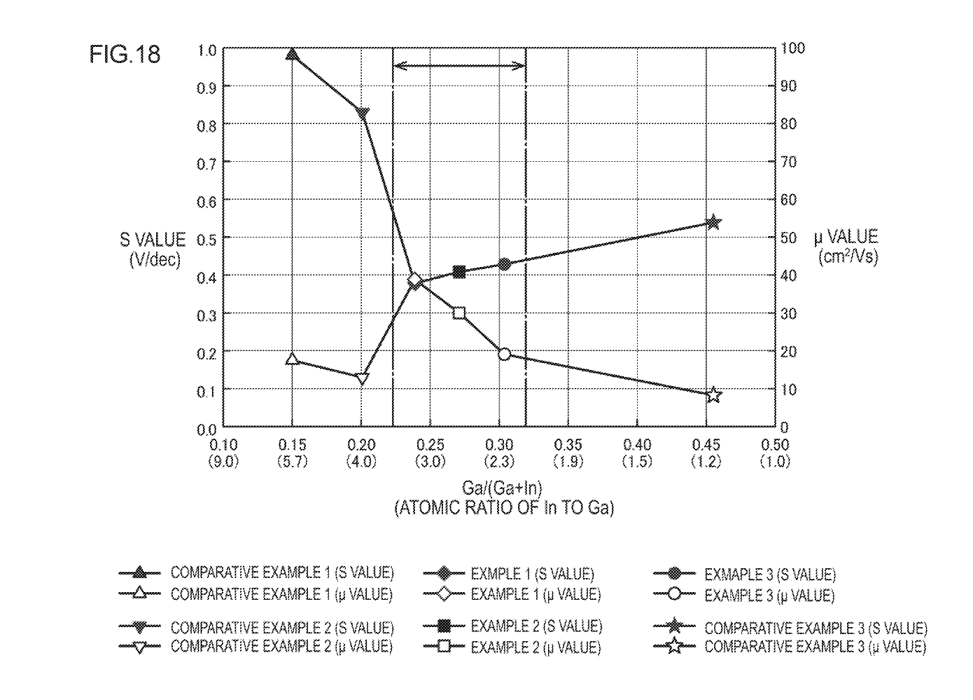

Next, Comparative Experiment 2 will be described. In Comparative Experiment 2, for the TFTs 11 including the oxide semiconductor films 17 having different atomic ratios “Ga/(Ga+In)”, drain currents Id were measured while changing gate voltage Vg. The oxide semiconductor films 17 having different atomic ratios “Ga/(Ga+In)” used in Comparative Experiment 2 are similar to those of Comparative Experiment 1 and the current was measured in Comparative Examples 1 to 3 and Examples 1 to 3 where the annealing treatment was performed under air atmosphere of 450° C. Measurement results are illustrated in FIGS. 11 to 16. The channel section 11d of the TFT 11 according to Comparative Examples 1 to 3 and Examples 1 to 3 has a channel length L and a channel width each of which is 6 μm. In the graphs of FIGS. 11 to 16, the vertical axis represents drain currents Id (a unit is “A”) and the horizontal axis represents gate voltages Vg (a unit is “V”), and the drain voltage is 10V. Furthermore, based on the measurement results illustrated in FIGS. 11 to 16, threshold voltage of the TFT 11, subthreshold swing value, and electron mobility in the channel section 11d are calculated and the calculated results are illustrated in FIGS. 17 and 18. The subthreshold swing value is gate voltage that is required to be applied in order to create a one decade increase in the current amount flowing from the source electrode 11b to the drain electrode 11c through the channel section 11d in the TFT 11. In the table of FIG. 17, Vth (a unit is “V”) representing the threshold voltage of the TFT 11, S values (a unit is “V/dec”) representing the subthreshold swing values, and μ values (a unit is “cm²/Vs”) representing the electron mobility in Comparative Examples 1 to 3 and Examples 1 to 3 are illustrated. The Vth is defined as the gate voltage Vg that is obtained when the drain current Id is 1 nA. In the graph of FIG. 18, the horizontal axis represents the atomic ratio “Ga/(Ga+In)” (the atomic ratio of In to Ga), and the vertical axis on the left side in FIG. 18 represents the S values (a unit is “V/dec”) and the vertical axis on the right side in the drawing represents the μ values (a unit is “cm²/Vs”). In the graph of FIG. 18, white plots represent the μ values and black plots represent the S values.

Experiment results of Comparative Example 2 will be described. According to the graphs of FIGS. 11 to 16, in Comparative Examples 1 to 3, the inclination of the graphs are more gentle and the variation rate of the drain current to the gate voltage is smaller than Examples 1 to 3, and accordingly, the S values are increased while the μ values being decreased. Especially, in Comparative Examples 1 and 2, as illustrated in FIGS. 17 and 18, the S values are extremely greater compared to those of Comparative Example 3 and Examples 1 to 3 and much greater than 0.5 V/dec (0.98 V/dec in Comparative Example 1, and 0.83 V/dec in Comparative Example 2). Therefore, the transistor characteristics are extremely deteriorated. From the above-described experiment results of Comparative Experiment 1, it is assumed that a main reason of such extreme increase of the S values in Comparative Examples 1 and 2 is the bixbyite structure of a cubic crystal system of indium oxide that is present in Comparative Examples 1 and 2. In Comparative Example 3, the μ value is 8.5 “cm²/Vs that is a smallest value and it is assumed that a main reason of such a smallest value is that the atomic ratio “Ga/(Ga+In)” is largest, which means that the atomic ratio of In to Ga is smallest, and the Vth is largest.

According to the graphs in FIGS. 11 to 16, in Examples 1 to 3, the inclination of the graphs in the linear section is steeper and the variation rate of the drain current to the gate voltage is greater than that of Comparative Examples 1 to 3. Accordingly, the S values are decreased while the μ values being increased. It is assumed that such steep inclination of the graphs is caused because the Vths are lower than 1 V and the drain voltage in a saturated section is 10-4 or more. Especially in Examples 1 and 2, as illustrated in FIGS. 17 and 18, the μ value is a quite great value such as 30 cm²/Vs or greater. Especially, in Example 1, the μ value is 39.0 cm²/Vs that is a greatest value and the S value is 0.38 V/dec that is smaller than 0.4 V/dec and is a smallest value. Namely, the transistor characteristics are best in Example 1. In FIG. 18, in a section represented with an arrow (a section where the atomic ratio Ga/(Ga+In) is about 0.22 to about 0.315), the μ value is about 18.0 cm²/Vs or more and the S value is about 0.6 V/dec or less, and good transistor characteristics are obtained.

As described before, the TFT (thin film transistor) 11 according to this embodiment at least includes the gate electrode 11a, the channel section 11d formed from the oxide semiconductor film 17, the source electrode 11b that is connected to one end of the channel section 11d, and the drain electrode 11c that is connected to another end of the channel section 11d. The oxide semiconductor film 17 is an oxide semiconductor at least containing gallium and indium and the atomic ratio Ga/(Ga+In) is in a range of 1/4.2 to 1/3.3.

According to the above configurations, if a signal is supplied to the gate electrode 11a, the electron moves from the source electrode 11b to the drain electrode 11c via the channel section 11d that is formed of the oxide semiconductor. If the oxide semiconductor film 17 of the channel section 11d has the atomic ratio Ga/(Ga+In) that is greater than 1/3.3, the subthreshold swing value (subthreshold coefficient) is greater than 0.5 V/dec and the switching properties of the TFT 11 may be deteriorated. This may be caused because the content ratio of indium oxide having a bixbyite structure of a cubic crystal system in the oxide semiconductor film 17 is increased and a defect density caused by grain boundaries is extremely great. If the atomic ratio Ga/(Ga+In) of the oxide semiconductor film 17 is smaller than 1/4.2, the electron mobility may be quite lower than 20 cm²/Vs because the atomic ratio of In to Ga in the oxide semiconductor film 17 may be too low. The atomic ratio Ga/(Ga+In) of the oxide semiconductor film 17 is within a range of 1/4.2 to 1/3.3 and accordingly, the subthreshold swing value is 0.5 V/dec or smaller and the electron mobility is 20 cm²/Vs or more so that the characteristics of the TFT 11 is improved.

The atomic ratio Ga/(Ga+In) of the oxide semiconductor film 17 may be within a range of 1/4.2 to 1/3.7, and the electron mobility in the oxide semiconductor film 17 is 30 cm²/Vs or more so that the characteristics of the TFT 11 are further improved.

The atomic ratio Ga/(Ga+In) of the oxide semiconductor film 17 is 1/4.2, and the subthreshold swing value in the oxide semiconductor film 17 is smallest and the electron mobility is highest so that the characteristics of the TFT 11 is further improved.

### Other Embodiments

The present invention is not limited to the embodiments described above and illustrated by the drawings. For examples, the following embodiments will be included in the technical scope of the present invention.

(1) Other than the above embodiment, a peripheral circuit such as a gate driver monolithic (GDM) circuit may be arranged in a non-display section of the array board of the liquid crystal panel. A peripheral circuit TFT included in the peripheral circuit has a substantially same structure (such as the channel section formed from the oxide semiconductor film) as the TFT arranged in the display section. Therefore, the channel section of the peripheral circuit TFT also has a great μ value and a small S value and the transistor characteristics are good. Accordingly, the peripheral circuit TFT and the peripheral circuit can be downsized and a frame area (the non-display section) of the liquid crystal panel and the array board can be reduced, and design properties can be improved.

(2) In the above embodiment, the oxide semiconductors included in the oxide semiconductor film may be amorphous but may preferably be crystalline having crystalline qualities. The oxide semiconductors having the crystalline qualities may preferably be polycrystalline oxide semiconductors, microcrystalline oxide semiconductors, or crystalline oxide semiconductors where c-axis is oriented substantially vertical to a layer surface. The oxide semiconductor film may have a multilayer structure including two or more layers. The oxide semiconductor film having a multilayer structure may include an amorphous oxide semiconductor layer and crystalline oxide semiconductor layer, or may include crystalline oxide semiconductor layers having different crystal structures. The oxide semiconductor film may include amorphous oxide semiconductor layers. In a two-layer structure of the oxide semiconductor film including an upper layer and a lower layer, an energy gap of the oxide semiconductors included in the upper layer is preferably greater than an energy gap of the oxide semiconductors included in the lower layer. If the difference between the energy gaps of the layers is relatively small, the energy gap of the oxide semiconductors included in the lower layer may be greater than the energy gap of the oxide semiconductors included in the upper layer. Material, structures, and film forming methods of amorphous oxide semiconductors and each of the above crystalline semiconductors and configurations of the oxide semiconductor film having a multilayer structure are described in Japanese Patent Unexamined Publication Application No. 2014-007399. For reference, the entire content of JPA 2014-007399 is hereby incorporated by reference.

(3) In the above embodiment, the oxide semiconductor film includes the oxide semiconductor containing gallium and indium. However, the oxide semiconductor film may contain elements other than gallium, indium, and oxygen.

(4) Other than the above embodiment, specific material of insulation films such as the gate insulation film, the interlayer insulation film, and the flattening film may be appropriately altered.

(5) Other than the above embodiment, metal material used for the first metal film and the second metal film may be altered as appropriate. A stacking structure of the first metal film and the second metal film may be altered as appropriate. For example, the number of layers may be altered, or the first metal film and the second metal film may have a single layer structure or may have an alloy structure.

(6) Other than the above embodiment, the transparent electrode material used for the transparent electrode film may be altered as appropriate. For example, transparent electrode material such as indium tin oxide (ITO) or zinc oxide (ZnO) may be used.

(7) In the above embodiment, the liquid crystal panel including a vertical alignment (VA) mode as an operation mode includes only one layer of the transparent electrode film on the array board. However, two layers of transparent electrode films maybe included having the interlayer insulation film therebetween. In such a configuration, one of the transparent electrode film may form the pixel electrode and another one may form an auxiliary capacitance electrode that forms static capacitance with the pixel electrode.

(8) In the above embodiment, the channel section does not include an etch stop layer and a lower edge surface of the source electrode on the channel section side is contacted with an upper surface of the oxide semiconductor film. However, TFTs of an etch stop type including an etch stop layer in an upper layer of the channel section may be used.

(9) The above embodiment includes the liquid crystal panel that includes a vertical alignment (VA) mode as an operation mode. However, other liquid crystal panels are also included in the scope of the present invention, for example, a liquid crystal panel that includes an in-plane switching (IPS) mode or a fringe field switching (FFS) mode as an operation mode is also included in the scope of the present invention.

(10) In the above embodiment, the liquid crystal panel includes display pixels of three colors including red, green, and blue. In addition to the red, green and blue display pixels, yellow display pixel may be included and the liquid crystal panel including display pixels of four colors is also included in the scope of the present invention.

(11) The above embodiment may further include a functional panel, such as a touch panel and a parallax barrier panel (a switching liquid crystal panel), layered and attached to the liquid crystal panel.

(12) In the above embodiment, the TFT included in the liquid crystal panel is described as the embodiment. However, TFTs that may be included in other types of display panels (e.g., plasma display panels (PDPs), organic EL panels, electrophoretic display (EPD) panels, micro electro mechanical systems (MEMS) display panels) are also included in the scope of the present invention.

### Explanation of Symbols

11: TFT (thin film transistor), 11a: gate electrode, 11b: source electrode, 11c: drain electrode, 11d: channel section, 17; oxide semiconductor film

1. A thin film transistor comprising:
a gate electrode;
a channel section formed of an oxide semiconductor film;
a source electrode connected to one end of the channel section; and
a drain electrode connected to another end of the channel section, wherein
the oxide semiconductor film is an oxide semiconductor containing at least gallium and indium and an atomic ratio Ga/(Ga+In) is from 1/4.2 to 1/3.3.

2. The thin film transistor according to claim 1, wherein
in the oxide semiconductor film, the atomic ratio Ga/(Ga+In) is from 1/4.2 to 1/3.7.

3. The thin film transistor according to claim 1, wherein
in the oxide semiconductor film, the atomic ratio Ga/(Ga+In) is 1/4.2.
